(19) United States
(12) Patent Application Publication
(10) Pub. No.: US 2022/0120793 A1
(43) Pub. Date: Apr. 21, 2022

(54) MEASURING DEVICE, ARRANGEMENT AND METHOD FOR CYCLIC MEASURED VALUE TRANSMISSION

(71) Applicant: VEGA GRIESHABER KG, Wolfach (DE)

(72) Inventors: Andreas ISENMANN, Haslach im Kinzigtal (DE); Martin GAISER, Alpirsbach (DE)

(73) Assignee: VEGA GRIESHABER KG, Wolfach (DE)

(21) Appl. No.: 17/504,213

(22) Filed: Oct. 18, 2021

(30) Foreign Application Priority Data
Oct. 19, 2020 (DE) 10 2020 127 496.3

(51) Int. Cl. G01R 21/133

(52) U.S. Cl. CPC G01R 21/133

(57) ABSTRACT

A measuring device of process automation in an industrial environment, which is arranged to receive configuration data and to generate measurement data, wherein both the configuration data and the measurement data are data to be transmitted to a measurement data receiving device via a cloud, and wherein the measuring device is arranged to transmit only the measurement data and an identification information to the cloud.

### CROSS-REFERENCE TO RELATED APPLICATIONS

This application claims the benefit of the filing date of German Patent Application No. 10 2020 127 496.3 filed on 19 Oct. 2020, the entire content of which is incorporated herein by reference.

### FIELD

The disclosure relates to a measurement data receiving device of process automation in an industrial environment, a method for cyclic transmission of measurement values in process automation in an industrial environment, a program element and a computer-readable medium.

### BACKGROUND

Measurement values in process automation can be transmitted at certain time intervals, e.g., to a cloud, in order to be retrieved from there by a display device. A service, for example a server, receives and stores the data. In order to be able to allocate the data and interpret and display it on a display device that accesses this server, or accesses the memory via the service, not only the measurement values but also context data are transmitted. Since this happens at regular intervals, large amounts of data are constantly accumulating, especially when many measuring devices send their data.

### SUMMARY

An objective of the disclosure is therefore to reduce the amount of data to be transmitted.

The objective is solved by the subject-matter of the independent patent claims. Advantageous embodiments are the subject of the dependent claims, the following description, and the figures.

The described embodiments similarly relate to the measurement data receiving device of the process automation in the industrial environment, the method for cyclic transmission of measurement values in the process automation in the industrial environment, the program element and the computer-readable medium. Synergistic effects may result from various combinations of the embodiments, although they may not be described in detail.

It should also be noted that all embodiments involving a method may be carried out in the order of steps described, but this need not be the sole and essential order of the steps of the method. The methods disclosed herein may be carried out with a different order of the disclosed steps without departing from the particular method embodiment, unless otherwise expressly stated below.

According to a first aspect, there is provided a measuring device of process automation in an industrial environment arranged to receive configuration data and to generate measurement data, wherein both the configuration data and the measurement data are data to be transmitted to a measurement data receiving device via a cloud, and wherein the measuring device (106) is arranged to transmit only the measurement data and an identification information to the cloud.

A process automation measuring device is, for example, a sensor or an energy monitoring device, as described in more detail below. The measuring device receives configuration data, such as in which physical unit generated measurement values are output. Further, it receives information with which the measuring device can be identified, such as a serial number, or with which the data can be associated with that measuring device. Further, it generates measurement data such as measurement value and for example a status of the measuring device. In order to display the measurement data correctly and in order to display additional information based on the configuration, configuration data must be communicated to a measurement data receiving device, such as a display device, in addition to the measurement data. The measurement device is configured to transmit only the measurement data and the identification information to the cloud, specifically a service in the cloud. The measuring device may here, for example, also be a sensor which accesses both types of data by default, but which additionally has a filter which prevents the transmission of configuration data to the cloud. The filter could be configurable in this case. For example, the configuration data could each contain a flag indicating whether, or which, configuration data should be transmitted. In this case, the configuration data to be transmitted would be assigned to the identification information or, as an exception, to the measurement data. In any case, the aim is to provide no or at most a small part of the data received as configuration for transmission. In the following, the identification information is assigned to both the configuration data and the measurement data and is specifically mentioned when its importance is to be emphasized.

According to a further aspect, there is provided a measurement data receiving device of process automation in an industrial environment configured to receive measurement data of a measurement device, i.e., only the measurement data, from a measurement value service in a cloud, to receive backup data of a configuration of the measurement device from a configuration backup service in a cloud, and to merge the measurement data and the backup data.

The configuration backup service is independent of the measurement value service. The measurement data receiving device must therefore establish two connections that are different from each other, for example a first connection via a first channel to the measurement value service and a second connection via a second channel to the configuration backup service. The measurement data is different from, but complementary to, the configuration backup data of the backup service. For example, the measurement data includes measurement values of the measurement device and the configuration backup data includes, for example, the associated physical unit, or an interpretation of the measurement values, such as the mathematical relationship of a fill level to a volume, where the measurement values indicate the fill level. The measurement data and the configuration are each transmitted with, for example, identification information, such as a serial number, so that the measurement data receiving device can associate the measurement data with the configuration backup data. The measurement data receiving device then combines the received data based on the identification information. The combined data then corresponds to that received in a conventional manner from the measurement data service. For example, the measurement data may be received cyclically, whereas the backup data may also be received cyclically, but the data is stored locally and is only retrieved or received as needed or on a one-time basis.

Process automation in the industrial environment can be understood as a subfield of technology that includes all measures for the operation of machines and plants without the involvement of humans. One goal of process automation is to automate the interaction of individual components of a plant in the chemical, food, pharmaceutical, petroleum, paper, cement, shipping or mining industries. For this purpose, a variety of sensors can be used, which are especially adapted to the specific requirements of the process industry, such as mechanical stability, insensitivity to contamination, extreme temperatures and extreme pressures. Measurement values from these sensors are usually transmitted to a control room, where process parameters such as fill level, limit level, flow rate, pressure or density can be monitored and settings for the entire plant can be changed manually or automatically.

A subarea of process automation or process automation in the industrial environment concerns logistics automation. With the help of distance and angle sensors, processes within a building or within an individual logistics facility are automated in the area of logistics automation. Typical applications include systems for logistics automation in the area of baggage and freight handling at airports, in the area of traffic monitoring (toll systems), in retail, parcel distribution or also in the area of building security (access control). Common to the examples listed above is that presence detection in combination with precise measurement of the size and position of an object is required by the respective application. Sensors based on optical measurement methods using lasers, LEDs, 2D cameras or 3D cameras that measure distances according to the time-of-flight (ToF) principle can be used for this purpose.

Another subarea of process automation in the industrial environment concerns factory/production automation. Application cases for this can be found in a wide variety of industries such as automotive manufacturing, food production, the pharmaceutical industry or generally in the field of packaging. The goal of factory automation is to automate the production of goods by machines, production lines and/or robots, i.e. to let it run without the involvement of humans. The sensors used in this process and the specific requirements with regard to measuring accuracy when detecting the position and size of an object are comparable to those in the previous example of logistics automation.

According to one embodiment, the measurement data receiving device is a display device. The display device may then numerically and graphically display the measurement value, for example the level, the interpreted measurement values, for example a volume of liquid corresponding to the level, and further information, such as an identifier or tag. However, the measurement data receiving device may also be a device that collects data from different measurement devices and forwards it, for example, to one or different display devices.

According to another aspect, a process automation arrangement in an industrial environment is provided. The arrangement comprises a cloud measurement value module including a measurement value service and a cloud backup module including a configuration backup service. The measurement value service is configured to cyclically receive measurement data, i.e., exclusively measurement data of a measurement device, and to provide the received measurement data to a measurement data receiving device. The configuration backup service is configured to receive backup data of a configuration of the measurement device, and the configuration backup service is further configured to provide the backup data of the configuration to the measurement data receiving device.

According to an embodiment, the arrangement further comprises a measurement data receiving device described above, which is configured to receive the provided measurement data and the provided backup data. The measured data receiving device can thus receive the measurement value data and the backup data and link them together. The data is thus transmitted distributed over two connections or channels.

In an example, the measurement value service is set up to receive the data cyclically. The backup data can, but need not, be transmitted cyclically. Thus, the volume of data to be transmitted is reduced in each case via the connections to/from the measurement value service. The volume of backup data to be transmitted can be kept low, so that less data is also transmitted overall.

According to an embodiment, the arrangement comprises a user interface arranged to receive configuration from a user and send it to configuration backup service.

In an example, the user interface may be implemented in a mobile device, a tablet, or a computing device. In this case, an interface to the measurement device 106 is also provided, such that the measurement device is configured via this interface. The configuration is stored or backed up as backup data, and the backup data is sent to the configuration backup service.

According to an embodiment, the arrangement is configured to receive automatically generated backup data of the configuration. That is, the configuration of the measuring device, and thus also the backup data, need not be generated by a user, but can also be generated automatically, for example by using artificial intelligence, and provided by a computing unit.

According to one embodiment, the measurement data is data from a sensor or energy monitoring unit. Such a sensor is, for example, a level sensor, a point level sensor, a pressure sensor, a temperature sensor, a sensor that measures a density or a composition or mixture of a substance during a process, and so on. An energy monitoring unit monitors, for example, a current, a voltage, a resistance, or similar electrical quantities.

According to an embodiment, the configuration backup data includes identification information, such as a serial number of the measuring device. The measurement data also includes the identification information of the measuring device. The measurement data receiving apparatus is adapted to perform merging of the measurement data and the configuration backup data using an association based on the identification information.

According to an embodiment, the measurement data comprises the serial number as identification information, as well as a measurement value and a status or status information. A status indicates, for example, whether the measuring device is OK or has a malfunction, or whether the measurement values are OK, i.e., for example, are within a permissible range.

According to an embodiment, the measurement service and the configuration backup service are each services in a cloud. However, the services may also be implemented in any other network.

According to a further aspect, a method for cyclic transmission of measurement values in process automation in an industrial environment is provided. The method comprises the following steps. In a first step, backup data of a configuration of a measuring device is received from a configuration backup service in the cloud and this backup data is provided to the measuring data receiving device. In a second step, measurement data of the measuring device, i.e. only measurement data, is received from a measurement data service in a cloud, e.g. cyclically, and this, i.e. only this measurement data is provided to a measurement data receiving device. In a third step, the measurement data and the backup data are merged by the measurement data receiving device. The method may comprise further steps according to the above description and the description of the figures.

The connection of the services for the cyclic measurement value transmission and the “backup of the configuration backup data” can thus be used by their combination for the display of the measurement value. This can significantly reduce the data volume for cyclic measurement value transmission.

According to a further aspect, there is provided a program element which, when executed on a control unit of an industrial process automation arrangement described above, instructs the arrangement to perform the steps of the method described above.

According to another aspect, a computer-readable medium on which such a program element is stored is provided. The program element may comprise a plurality of parts stored on different computer-readable media. That is, the program element is to be seen here as a whole and may be divided here, for example, into different processors or hardware units, each of which contains the different functional parts according to the different steps. In particular, the backup service and the measurement value service may be implemented either on different hardware or on the same hardware.

The program element may be part of a computer program, but it may also be an entire program in itself. For example, the computer program element may be used to update an existing computer program. The computer-readable medium may be considered a storage medium, such as a USB flash drive, a CD, a DVD, a data storage device, a hard drive, or any other medium on which a program element as described above may be stored.

Other variations of the disclosed embodiments may be understood and carried out by those skilled in the art in carrying out the claimed invention by studying the drawings, the disclosure, and the appended claims. In the claims, the word “comprising” does not exclude other elements or steps, and the indefinite article “a” or “an” does not exclude a plurality. A single processor or other entity may perform the functions of multiple items or steps recited in the claims. The mere fact that certain actions are recited in interdependent claims does not mean that a combination of those actions cannot be advantageously used.

A computer program may be stored/distributed on a suitable medium such as an optical storage medium or a semiconductor medium supplied with or as part of other hardware, but may also be distributed in other forms, for example via the Internet or other media wired or via wireless telecommunications arrangements. Reference signs in the claims should not be construed as limiting the scope of the claims.

### SHORT DESCRIPTION OF THE FIGURES

In the following, embodiments will be described in detail with reference to the accompanying figures. Neither the description nor the figures are intended to be construed as limiting the invention. Hereby shows

FIG. 1 a block diagram of a process automation arrangement in an industrial environment according to one embodiment, and

FIG. 2 a flow diagram of a method for cyclic transmission of measurement values in process automation in an industrial environment according to one embodiment.

The drawings are only schematic and not to scale. In principle, identical or similar parts are provided with the same reference signs.

### DETAILED DESCRIPTION

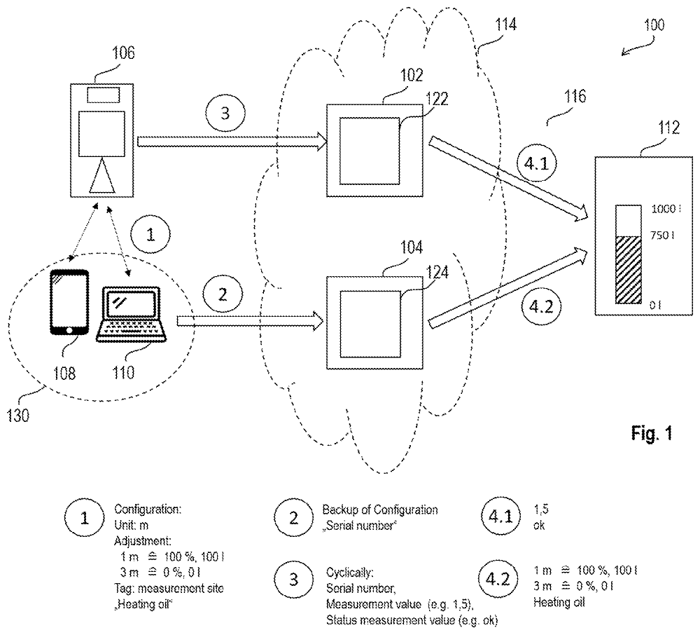

FIG. 1 shows a process automation arrangement 100 in an industrial environment.

The numbers 1, 2, 3, 4.1 and 4.2 in the circles indicate a possible sequence of a flow of data. Examples of the content of the data are assigned to the digits.

The arrangement 100 has a cloud measurement module 102 that includes a measurement service 122 and a cloud backup module 104 that includes a configuration backup service 124, the modules 102, 104 residing in a cloud 114. FIG. 1 further shows a measurement device 106, a smartphone 108, a computing device 110, and a display device 112.

A user creates a configuration for the measurement device 106. For example, the configuration includes data or information regarding the physical unit in which the measurement values are provided, information regarding the interpretation of the measurement values, and a tag, such as “measurement point heating oil” (see circle 1). The interpretation may, for example, establish a relationship between a level of a container and a volume of a medium contained in the container, also referred to herein as an “adjustment”. For example, a fill level of 1 m corresponds to a volume of 100 liters and a fill level of 3 m corresponds to a volume of 0 liters. The configuration is sent to the measuring device 106, for example, as a file (circuit 1). There may also be a client/server interface or a user interface on the measuring device, so that the configuration is made directly in the measuring device. In the former case, however, the data would still be stored locally at the same time, and in the latter case the configuration would be transmitted to either the smartphone 108 or the computing device 110. In either case, e.g., after the measuring device has been configured, the backup data of the configuration e.g., with a key “serial number” or including the serial number is also sent from the smartphone 108, the computing device 110, or from the measuring device itself as a backup to a backup service 104 in a network such as a cloud 114 (circle 2) and stored there.

While typically a configuration backup is only accessed if the data in the device is lost, or the measurement device 106 is replaced with, for example, a device that is to receive the same configuration backup data, the backup service 104 in the cloud 114 now provides that data to another device, such as a display device 112.

With cyclic measurement value transmission, only the serial number, the measurement value, e.g., the distance value and the current status of the measuring point are now transmitted to the cloud service provided for this purpose, e.g., the measurement value service.

The display device 112 may retrieve the required backup data on a regular or one-time basis, or retrieve it on demand, for example, when it determines that it is missing the necessary data. For example, the measurement values and the configuration backup data may be retrieved synchronously or quasi-synchronously. However, the display device may also retrieve them once and store them locally. In case of a change of the configuration, for example, the serial number could be changed, so that the display device performs a query again to obtain the changed data.

The architecture may also be varied in this regard so that, for example, an intermediate unit between the services 122, 124 and the display device 112 compiles the data from the latter and possibly other devices and the display device 112 retrieves the compiled data. At the intermediate unit, the data from a plurality of configuration devices and measurement values may converge and be retrieved accordingly by a plurality of display devices, or one display device may display measurement values from different measuring devices.

All connections, e.g., between configuration devices 108, 110 to the measuring device 106, the connection to the cloud and the connection to the display device may be implemented wirelessly, e.g., via mobile radio or according to a wireless standard, or wired. Wired standards include, for example, fieldbuses, Ethernet, serial ports, etc. Advantageously, the devices involved communicate via the IIoT (Industrial Internet of Things). A configuration could also be created directly at the measuring device, from which the data is then transmitted to the smartphone 108 or the computing device 110.

The computing device 110 may be a tablet, a PC, a notebook, a dedicated device, or any other device capable of and adapted to perform the tasks described.

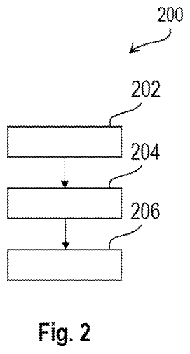

FIG. 2 illustrates a method 200 for cyclically transmitting measurement data in process automation in an industrial environment, comprising the steps of:

Receiving 202 backup data of a configuration of a measurement device 106 and providing or sending the measurement data to the measurement data receiving device 112 through a configuration backup service 124 in the cloud 114.

Receiving 204 measurement data from the measurement device 106 and providing or sending the received measurement data to the measurement data receiving device 112 through a measurement data service 122 located in the cloud 114.

Receiving 206 the provided backup data and the provided measurement data and merging the provided backup data and the provided measurement data by a measurement data receiving device 112. The measurement data may then be displayed in a desired manner in the measurement data receiving device 112, such as a display device.

Thus, a reduction of the amount of data during the cyclic transmission of the measurement value via a first communication channel and the use of the backup data of the configuration transmitted via a second communication channel for displaying the measurement value can be achieved.

1. A measuring device for process automation in an industrial environment, comprising:
circuitry configured to receive configuration data and to generate measurement data,
wherein both the configuration data and the measurement data are transmittable to a measurement data receiving device via a cloud, and
wherein the circuitry is further configured to transmit only the measurement data and an identification information to the cloud.

2. A measurement data receiving device—for process automation in an industrial environment, comprising:
circuitry configured to:
receive measurement data of a measurement device from a measurement value service in a cloud,
receive backup data of a configuration of the measuring device from a configuration backup service in the cloud, and
merge the measurement data and the backup data.

3. The measurement data receiving device according to claim 2, wherein the measurement data receiving device is a display device.

4. An industrial process automation arrangement comprising:
cloud measurement value circuitry configured to implement a measurement value service; and
cloud backup circuitry configured to implement a configuration backup service (124), wherein
the measurement value service is configured to receive measurement data from a measurement device and to provide the received measurement data to a measurement data receiving device,
the configuration backup service is configured to receive backup data of a configuration of the measuring device, and
the configuration backup service is further configured to provide the backup data of the configuration of the measuring device to the measurement data receiving device.

5. The industrial process automation arrangement according to claim 4, wherein the arrangement further comprises the measuring device for process automation in an industrial environment, comprising:
circuitry configured to receive configuration data and to generate measurement data,
wherein both the configuration data and the measurement data are transmittable to a measurement data receiving device via a cloud, and
wherein the circuitry is further configured to transmit only the measurement data and an identification information to the cloud.

6. The industrial process automation arrangement according to claim 4, wherein the arrangement further comprises a measurement data receiving device, which is configured to receive the provided measurement values and the provided backup data, and wherein the measurement data receiving device is for process automation in an industrial environment and includes
circuitry configured to:
receive measurement data of a measurement device from a measurement value service in a cloud,
receive backup data of a configuration of the measuring device from a configuration backup service in the cloud, and
merge the measurement data and the backup data

7. The industrial process automation arrangement according to claim 4, wherein the arrangement further comprises a user interface configured to receive the configuration from a user and to send the configuration to the configuration backup service.

8. The industrial process automation arrangement according to claim 4, wherein the cloud measurement value service and the configuration backup service are further configured to automatically receive generated backup data of the configuration.

9. The industrial process automation arrangement according to claim 4, wherein the measurement data is data from a sensor or an energy monitoring circuit.

10. The industrial process automation arrangement according to claim 4, wherein
the backup data includes identification information of the measuring device,
the measurement data includes the identification information of the measuring device, and
the measurement data receiving device is further configured to perform merging of the measurement data and the backup data using an association based on the identification information.

11. The industrial process automation arrangement according to claim 4, wherein the measurement data includes a serial number as identification information, a measurement value, and a status.

12. The industrial process automation arrangement according to claim 4, wherein the measurement value service and the configuration backup service are each services in a cloud.

13. A method for cyclic transmission of measurement values in process automation in an industrial environment, comprising:
receiving backup data of a configuration of a measuring device and providing the backup data to a measuring data receiving device by a configuration backup service in a cloud;
receiving measurement data of the measurement device and providing the measurement data to the measurement data receiving device through a measurement data service in the cloud, and
merging the measurement data and the backup data by the measurement data receiving device.

14. A non-transitory computer-readable medium on which is stored a program element implementing the method according to claim 13.

15. The industrial process automation arrangement according to claim 5, wherein the arrangement further comprises a measurement data receiving device which is configured to receive the provided measurement values and the provided backup data, and wherein the measurement data receiving device is for process automation in an industrial environment and includes
circuitry configured to:
receive measurement data of a measurement device from a measurement value service in a cloud,
receive backup data of a configuration of the measuring device from a configuration backup service in the cloud, and
merge the measurement data and the backup data.

16. The industrial process automation arrangement according to claim 5, wherein the arrangement further comprises a user interface configured to receive the configuration from a user and to send the configuration to the configuration backup service.

17. The industrial process automation arrangement according to claim 6, wherein the arrangement further comprises a user interface configured to receive the configuration from a user and to send the configuration to the configuration backup service.

18. The industrial process automation arrangement according to claim 5, wherein the circuitry is further configured to automatically receive generated backup data of the configuration.

19. The industrial process automation arrangement according to claim 6, wherein the cloud measurement value service and the configuration backup service are further configured to automatically receive generated backup data of the configuration.

20. The industrial process automation arrangement according to claim 7, wherein the cloud measurement value service and the configuration backup service are further configured to automatically receive generated backup data of the configuration.
